(19) United States
(12) Patent Application Publication
(10) Pub. No.: US 2024/0195329 A1
(43) Pub. Date: Jun. 13, 2024

(54) TRIBOELECTRIC NANOGENERATOR (TENG) AND POWER GENERATION DEVICE BASED ON PLANT FIBER AND MODIFIED TRIBO-ELECTRONEGATIVE MATERIAL

(71) Applicant: ZHEJIANG UNIVERSITY, Hangzhou (CN)

(72) Inventors: Yibin YING, Hangzhou (CN); Shufen DAI, Hangzhou (CN); Xunjia LI, Hangzhou (CN); Jianfeng PING, Hangzhou (CN)

(73) Assignee: ZHEJIANG UNIVERSITY, Hangzhou (CN)

(21) Appl. No.: 18/586,614

(22) Filed: Feb. 26, 2024

Related U.S. Application Data
(63) Continuation of application No. PCT/CN2022/109945, filed on Aug. 3, 2022.

(30) Foreign Application Priority Data
Apr. 26, 2022 (CN) 202210448298.7
Apr. 26, 2022 (CN) 202210449552.5
Apr. 26, 2022 (CN) 202210449601.5

(51) Int. Cl. H02N 1/04; F03B 7/00

(52) U.S. Cl. CPC H02N 1/04; F03B 7/00; F05B 2220/706

(57) ABSTRACT

A triboelectric nanogenerator (TENG) and a power generation device based on a plant fiber and a modified tribo-electronegative material is provided. A rotor is located inside a stator. An inner circumferential surface of the stator is provided with copper, and an outer circumferential surface of the rotor is provided with a tribo-electronegative material. The tribo-electronegative material is not in contact with the copper, and an air gap is formed between the tribo-electronegative material and the copper. The inner circumferential surface of the stator is further provided with a plant fiber brush. During rotation, the tribo-electronegative material scrapes the plant fiber brush to allow soft contact to transfer charges. The rotor is axially connected to a driving shaft of a waterwheel, and the TENG operates under an action of a water flow. The tribo-electronegative material is obtained by etching a film to form a nano-textured structure and depositing a fluorocarbon layer.

### CROSS REFERENCE TO THE RELATED APPLICATIONS

This application is the continuation application of International Application No. PCT/CN2022/109945, filed on Aug. 3, 2022, which is based upon and claims priority to Chinese Patent Applications No. 202210449601.5, No. 202210449552.5, and No. 202210448298.7, all filed on Apr. 26, 2022, the entire contents of which are incorporated herein by reference.

### TECHNICAL FIELD

The present disclosure relates to a triboelectric nanogenerator (TENG) in the technical field of new energy, and in particular relates to a soft-contact and low-damping TENG based on a plant fiber brush and a modified tribo-electronegative material, and a plant fiber-based soft-contact and low-damping triboelectric nano-power generation device configured to harvest low-flow-rate water energy.

### BACKGROUND

Water energy is one of the most common, sustainable, and accessible clean and renewable energy sources in the agricultural environment, has a large quantity, and is expected to be utilized on a large scale. TENG has advantages such as high power density, light weight, low cost, and diversified materials and structures, and thus is used to efficiently harvest water energy. Currently, TENG is mainly used to harvest marine energy, but there are few studies on the use of TENG to harvest low-speed and low-frequency flowing energy (such as river energy and irrigation energy) in the agricultural environment. River water and agricultural irrigation water in the nature have a relatively low flow rate, and the traditional TENG has a relatively large operation damping and generally cannot be used to harvest low-flow-rate water energy.

For the conventional TENG, the sufficient friction of a friction pair in direct contact is necessary to increase triboelectric charges and an output power density, but a long-term operation may cause severe wear and reduce the life cycle of the device. So far, various efforts have been made to improve the durability of the device, such as structural designs of rolling charging, pendulum movement, an electric brush, and automatic mode switching (AMS). In the previous efforts, it has been confirmed that a soft-contact operation mode of TENG is an effective strategy for improving the durability.

Soft-contact TENG can avoid a direct contact of a friction pair, improve the durability of the device, and reduce the damping of the device during an operation process. In the previous efforts, a soft-contact operation mode of TENG typically adopts an animal hair as a soft-contact material and a charge transfer medium. Plant fibers are soft, and can be in close contact with another triboelectric layer when rubbed against the triboelectric layer, resulting in low resistance. The introduction of a flexible plant fiber as a triboelectric material in TENG can increase tribo-electropositive charges injected into a dielectric surface, greatly reduce the wear of the material, and increase the output density and durability of TENG. As the output density and the durability of TENG increase, an external driving force of TENG can be significantly reduced.

Currently, there is no TENG prepared based on a plant fiber soft-contact material. Therefore, the present disclosure designs and manufactures a plant fiber-based soft-contact TENG (PFB-TENG) to harvest low-flow-rate river and irrigation energy. Plant fiber brushes such as soft Gossypium are typical tribo-electropositive materials, and etched polyvinyl chloride (PVC) has strong tribo-electronegativity due to large surface roughness and introduction of fluorine. Therefore, a friction pair can effectively convert weak mechanical energy into electrical energy. Compared with various hard-contact competitors, PFB-TENG exhibits increased transfer charges and improved output performance and durability at the same torque and speed, which means that the PFB-TENG designed can maximize the use of weak discrete kinetic energy in a low-flow-rate irrigation and river energy-harvesting environment.

### SUMMARY

In order to solve the problems existing in the background and fill the gap, an objective of the present disclosure is to introduce a plant fiber as a novel triboelectric material into a triboelectric generator and innovatively use a plant fiber brush-based soft-contact and low-damping TENG to harvest water energy, thereby providing a plant fiber-based soft-contact and low-damping triboelectric nano-power generation device configured to harvest water energy. The present disclosure also uses an inductively coupled plasma (ICP)-based dry etching technology to improve the triboelectric output performance of a PVC film, where etching is innovatively used to cover a fluorocarbon material layer on a surface of the PVC film while increasing surface roughness of the PVC film, which can improve the triboelectric output performance of the tribo-electronegative material, thereby improving the triboelectric power generation performance.

In the present disclosure, a soft-contact fiber brush is provided between electrodes on a surface of a stator near a rotor to allow a soft contact between a copper electrode and a PVC film to transfer charges.

The present disclosure adopts the following technical solutions:
1. A plant fiber brush-based soft-contact and low-damping TENG is provided, including:
a rotor, a stator, a copper electrode, a tribo-electronegative material, and a plant fiber brush, where the rotor is located inside the stator; an inner circumferential surface of the stator is covered with the copper electrode, and at least one position on an outer circumferential surface of the rotor is provided with the tribo-electronegative material; the tribo-electronegative material is not in contact with the copper electrode, and an air gap is formed between the tribo-electronegative material and the copper electrode; and at least one position on the inner circumferential surface of the stator is provided with the plant fiber brush.

During rotation of the rotor, the tribo-electronegative material scrapes the plant fiber brush to allow soft contact to transfer charges.

The low damping described in the present disclosure means that a damping is lower than 0.06 N·m. In an embodiment, when a Setaria viridis brush, a Phragmites australis brush, a Cortaderia selloana brush, and a Gossypium brush are adopted as charge-supplement materials, a working damping of the device is lower than 0.06 N·m, where the Gossypium brush leads to the smallest damping values at different rotational speeds, which all are lower than 0.05 N·m and can be as low as 0.015 N·m.

The plant fiber brush is prepared from a natural plant fiber, including soft fiber material-containing plants such as Gossypium, Phragmites australis, Cortaderia selloana, and Setaria viridis.

The outer circumferential surface of the rotor is provided with a plurality of tribo-electronegative materials in a circumferential direction.

The copper electrode is composed of interdigital electrodes arranged at an interval in an axial direction; and the interdigital electrodes are arranged on a substrate, and the substrate is fixed on and covers the inner circumferential surface of the stator.

The tribo-electronegative material is fixedly attached to a substrate, and is not in contact with the copper electrode.

The soft-contact and low-damping TENG can be used in the harvest of irrigation energy.

The TENG of the present disclosure may work in an independent layer mode, and specifically, the soft-contact and low-damping TENG includes an independent tribo-electronegative material and a pair of fixed interdigital copper electrodes. When a tribo-electronegative layer moves between two electrodes, a periodic charge change is induced to cause a potential change, and then the potential change drives electrons to flow between the two electrodes, thereby completing a power generation process. At least one position on the inner circumferential surface of the stator is provided with the plant fiber brush to supplement charges for the tribo-electronegative material. Similar to a single-electrode mode, this working mode does not require electrodes to be plated on a moving part of the device, which facilitates the fabrication and working of the device; and this working mode can also provide a higher energy conversion efficiency than the single-electrode mode, and provide higher output performance than the single-electrode mode due to no interference of a shielding effect of the single-electrode mode.
2. A plant fiber-based triboelectric nano-power generation device configured to harvest low-flow-rate water energy is provided, including:
the TENG described above and a waterwheel driving mechanism, where the rotor of the TENG is coaxially connected to a driving shaft of the waterwheel driving mechanism, and the waterwheel driving mechanism is driven under an action of a water flow to operate so as to drive the TENG to operate, and the waterwheel drives the rotor of the TENG to rotate under an action of external irrigation water energy, such that the TENG converts irrigation energy into electrical energy.

The low flow rate described in the present disclosure means that a flow rate is lower than 1 m³/h. The present disclosure can allow the harvest of water energy at different flow rates of 0.5 m³/h, 0.6 m³/h, 0.7 m³/h, 0.8 m³/h, 0.9 m³/h, and 1 m³/h, and can allow the harvest of water energy at a minimum flow rate of 0.5 m³/h.

The waterwheel driving mechanism includes a waterwheel, a driving shaft, and a bearing seat; and the waterwheel is sleeved on the driving shaft, the driving shaft is supported on the bearing seat, and the driving shaft is coaxially connected to the rotor.

The plant fiber-based triboelectric nano-power generation device can be used in the harvest of irrigation energy or low-flow-rate water energy.

A preparation method of the tribo-electronegative material is as follows: etching an upper surface of a film by an ICP dry etching instrument to form a nano-textured structure on the upper surface of the film; and subjecting the upper surface of the film to a deposition treatment by an ICP etching instrument to deposit a fluorocarbon layer on an upper surface of the nano-textured structure.

In the present disclosure, ICP dry etching is adopted to improve the triboelectric output performance of a tribo-electronegative material.

The film is a PVC film.

The preparation method of the tribo-electronegative material specifically includes the following steps:
cleaning of a PVC film: ultrasonically cleaning the PVC film in absolute ethanol for 5 min to 10 min and then in deionized water for 5 min to 10 min, and drying a cleaned PVC film to obtain a clean PVC film;
placing the clean PVC film in a carrier for plasma etching, and delivering the carrier to a cavity of a plasma dry etching device;
vacuuming the plasma dry etching device to maintain a stable pressure, and allowing a process including two stages of etching and deposition; and
after the process is completed, controlling the plasma dry etching device to reach an ambient pressure state, and taking a resulting PVC film out.

The two stages of etching and deposition are specifically as follows:
a first stage: introducing 15 sccm O₂ and 45 sccm CHF₃, controlling an ICP power at 100 W, and conducting etching for 10 min; and
a second stage: introducing 50 sccm C₄F₈, controlling an ICP power at 100 W, and conducting deposition for 10 s.

The tribo-electronegative material of the present disclosure may be used in TENG.

The plant fiber material provided in the present disclosure is an excellent soft charge-supplement material, which can make up for a charge loss of a device during an operation of the device, reduce a wear caused by direct contact between a copper electrode and a PVC film, improve the durability and output power density of TENG, and reduce a damping of TENG during an operation.

The present disclosure has the following beneficial effects:

Compared with the independent-layer soft-contact and low-damping TENG previously reported, the present disclosure uses a soft natural plant fiber brush in preparation of TENG for the first time, which reduces the damping of TENG during an operation, thereby allowing the harvest of low-flow-rate water energy. The introduction of the plant fiber brush improves the durability and output power density of TENG and reduces the damping of TENG during an operation. Therefore, a plant fiber-based TENG can work under a small driving force.

In the present disclosure, a soft plant fiber brush is used as a charge transfer medium, which can avoid direct contact of a friction pair, reduce a damping of a device during an operation, and improve the durability of a device. Plant fibers are soft, and can be in close contact with another triboelectric layer when rubbed against the triboelectric layer, resulting in low resistance.

In the present disclosure, the introduction of flexible plant fiber as a triboelectric material in TENG can increase tribo-electropositive charges injected into a dielectric surface, greatly reduce wear of the material, increase an output density and durability of TENG, and allow the harvest of low-flow-rate water energy.

In the present disclosure, an upper surface of a PVC film is etched by a plasma etching technology for a period of time to form a nano-textured structure on the upper surface of the PVC film, which increases the roughness of the PVC film, a specific surface area (SSA), and a surface charge-carrying capacity, thereby increasing the triboelectric output performance; and after the etching is completed, the upper surface of the PVC film is subjected to a deposition treatment by plasma etching for a period of time to deposit a fluorocarbon layer on an upper surface of the nano-textured structure of the PVC film. The covering of the fluorocarbon layer on the surface of the film can improve the electron-receiving ability of the film and increase the tribo-electronegativity.

### BRIEF DESCRIPTION OF THE DRAWINGS

FIG. 1 is a schematic structural diagram of a plant fiber brush-based TENG;

FIG. 2 shows optical microscopic images of four plant fiber brushes;

FIGS. 3A-3D show the comparison of output performance of PFB-TENGs prepared with four plant fiber brushes, where FIG. 3A is a schematic diagram of a dynamic torque system configured to test the output performance of PFB-TENG; and FIGS. 3B-3D show output voltages, output currents, and transferred charge amounts of brush-free PFB-TENG, Setaria viridis brush-based PFB-TENG, Phragmites australis brush-based PFB-TENG, Cortaderia selloana brush-based PFB-TENG, and Gossypium brush-based PFB-TENG, and it can be seen from FIGS. 3B-3D that PFB-TENG prepared with a Gossypium brush as a soft-contact material has the optimal output electrical performance;

FIG. 4 shows scanning electron microscopy (SEM) images of four plant fibers;

FIGS. 5A-5C show SEM images of a PVC tribo-electronegative material, where FIG. 5A is an SEM image of the original PVC film, FIG. 5B is an SEM image of the PVC film rubbed against a copper electrode 30,000 times, and FIG. 5C is an SEM image of the PVC film rubbed against a Gossypium fiber brush 30,000 times; and it can be seen from the images that, after the PVC film is rubbed against the Gossypium fiber brush, a very small wear is produced, indicating that the use of the Gossypium fiber brush as a charge-supplement material can improve the operation stability of a device;

FIG. 6 shows Fourier-transform infrared spectroscopy (FTIR) characterization results of four plant fibers;

FIG. 7 shows working damping values when four different plant fiber brushes are used as charge-supplement materials, and it can be seen from the figure that damping values produced by the four plant fiber brushes are ranked as follows from largest to smallest: Setaria viridis brush>Phragmites australis brush>Cortaderia selloana brush>Gossypium brush; and the damping values of the four plant fiber brushes all are lower than 0.06 N·m, where the Gossypium brush leads to the smallest damping values at different rotational speeds, which all are lower than 0.05 N·m;

FIG. 8 is a histogram of point integral values of hydroxyl contents in four fiber brushes determined by a multifunctional infrared (IR) nanospectrometer at 3,412 cm⁻¹;

FIG. 9 shows results of a cycling stability test of PFB-TENG prepared with a Gossypium fiber as a soft-contact material;

FIG. 10 shows power density curves of PFB-TENG;

FIG. 11 is a schematic structural diagram of a plant fiber-based triboelectric nano-power generation device;

FIG. 12 shows confocal microscopy and SEM images of four plant fiber brushes, where Gossypium, Cortaderia selloana, Phragmites australis, and Setaria viridis brushes are shown sequentially from left to right;

FIGS. 13A-13B show transferred charge amounts (FIG. 13A) and short-circuit currents (FIG. 13B) of PFB-TENG under actions of water flows at different flow rates;

FIG. 14 is an equivalent circuit diagram in which the plant fiber-based soft-contact and low-damping triboelectric nano-power generation device configured to harvest irrigation energy in the present disclosure serves as a power supply for a load resistor or capacitor;

FIG. 15 shows voltage changes of different capacitors charged by PFB-TENG driven by a water flow over time;

FIG. 16 shows some work cycles on a voltage curve of a soil sensor powered by PFB-TENG driven by a water flow;

FIG. 17 is a perspective view of a plant fiber-based TENG;

FIG. 18 shows SEM images of PVC films prepared in 6 embodiments;

FIGS. 19A-19F show white light interferometry (WLI) images of PVC films prepared in 6 embodiments, which characterize roughness values of the films;

FIGS. 20A-20F shows WLI three-dimensional (3D) images of PVC films prepared in 6 embodiments, which characterize thickness values of the films;

FIG. 21 shows roughness and thickness values of PVC films prepared in 6 embodiments;

FIG. 22 shows X-ray photoelectron spectroscopy (XPS) characterization results of PVC films prepared in 6 embodiments;

FIGS. 23A-23F show energy-dispersive X-ray spectroscopy (EDS) characterization results of PVC films prepared in 6 embodiments;

FIG. 24 shows carbon/fluorine ratios of PVC films prepared by plasma dry etching in Examples 1 to 5;

FIG. 25 is a schematic diagram of vertical-contact separation mode TENGs constructed with PVC films prepared in Examples 1 to 6;

FIG. 26 shows voltage signals of vertical-contact separation mode TENGs constructed with PVC films prepared in Examples 1 to 6;

FIGS. 27A-27F shows transferred charge amounts, output currents, and output voltages of TENGs prepared with an untreated control (FIGS. 27A-27C) and a PVC film etched by ICP-3 (FIGS. 27D-27E) at different rotational speeds;

FIG. 28 shows output power densities of TENG prepared with an untreated PVC film (control) at different matched resistances; and

FIG. 29 shows output power densities of TENG prepared with a PVC film etched by ICP-3 at different matched resistances.

Table 1 shows specific treatment processes of 6 embodiments and thickness and roughness statistics of prepared films.

In the figures: 1: rotor, 2: stator, 3: copper electrode, 4: tribo-electronegative material, 5: plant fiber brush, 6: air gap, 7: waterwheel, 8: driving shaft, and 9: bearing seat.

### DETAILED DESCRIPTION OF THE EMBODIMENTS

The present disclosure is described in further detail below with reference to the accompanying drawings and specific embodiments.

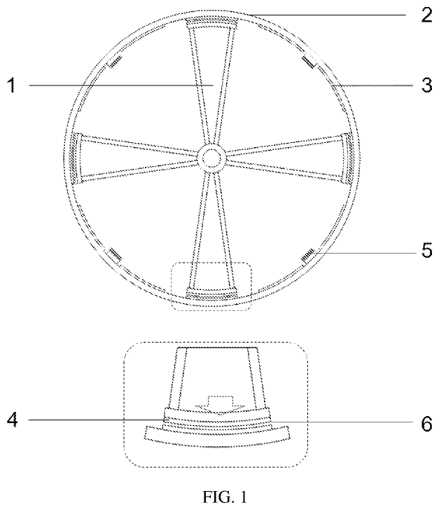

As shown in FIG. 1, a TENG of a specific embodiment includes rotor 1, stator 2, copper electrode 3, tribo-electronegative material 4, and plant fiber brush 5, where the rotor 1 is located inside the stator 2; an inner circumferential surface of the stator 2 is covered with the grid-like copper electrode 3, and at least one position on an outer circumferential surface of the rotor 1 is provided with the tribo-electronegative material 4; the tribo-electronegative material 4 is not in contact with the copper electrode 3, and air gap 6 of 0.5 mm to 1.5 mm is formed between the tribo-electronegative material 4 and the copper electrode 3; and at least one position on the inner circumferential surface of the stator 2 is provided with the soft plant fiber brush 5.

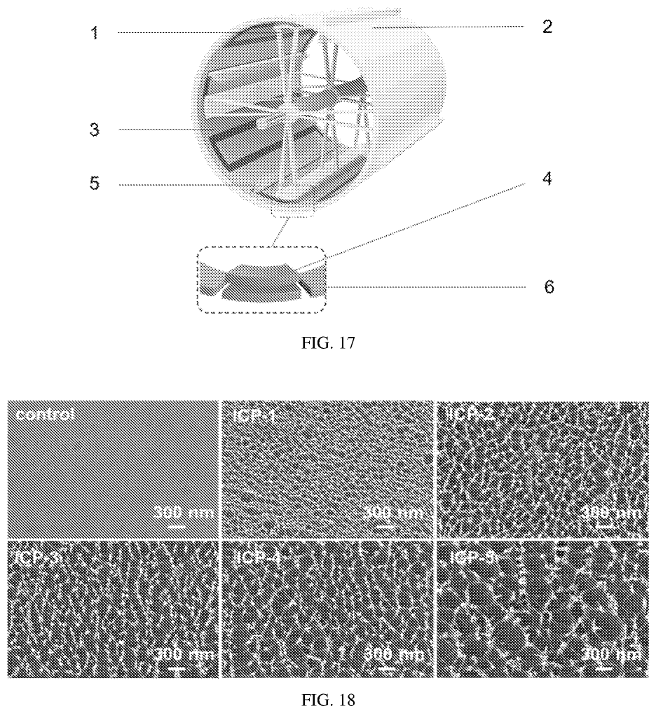

As shown in FIG. 17, a plant fiber-based triboelectric nano-power generation device of a specific embodiment include the TENG and a waterwheel driving mechanism, where the rotor 1 of the TENG is coaxially connected to driving shaft 8 of the waterwheel driving mechanism, and a rotation of waterwheel 7 of the waterwheel driving mechanism is driven under an action of a water flow to drive the triboelectric nano-power generation device to operate. During rotation of the rotor 1, the tribo-electronegative material 4 scrapes the plant fiber brush 5 to allow soft contact to transfer charges, which can improve the triboelectric nano-power generation performance.

The plant fiber brush 5 is prepared from a natural plant fiber, including soft fiber material-containing plants such as Gossypium, Phragmites australis, Cortaderia selloana, and Setaria viridis; and the brush is in contact with the tribo-electronegative material on the stator.

The tribo-electronegative material 4 is fixedly attached to a substrate, and is not in contact with the copper electrode 3. In a specific embodiment, a polyimide (PI) tape is applied to the outer circumferential surface of the rotor, and then the tribo-electronegative material 4 is pasted on the outer circumferential surface of the rotor.

During rotation of the rotor 1, the tribo-electronegative material 4 scrapes the plant fiber brush 5 to allow soft contact to transfer charges, which can improve the triboelectric nano-power generation performance.

The outer circumferential surface of the rotor 1 is provided with a plurality of tribo-electronegative materials 4 in a circumferential direction, and the plurality of tribo-electronegative materials 4 are evenly arranged at an interval in a circumferential direction. The tribo-electronegative material 4 is fixedly attached to a substrate, and is not in contact with the copper electrode 3. In a specific embodiment, a mounting groove is formed on the substrate, and the tribo-electronegative material 4 is fixed in the mounting groove.

The copper electrode 3 is composed of interdigital electrodes arranged at an interval in an axial direction; and the interdigital electrodes are arranged on a substrate, and the substrate is fixed on and covers the inner circumferential surface of the stator 2. Spaced copper electrodes are connected in series, and two adjacent copper electrodes are not connected to each other, that is, copper electrodes are divided into two groups that are not connected to each other. A layer of grid-like copper electrodes prepared by a flexible printed circuit board (FPCB) technology is attached to an inner wall of a shell, and a width of a grid of the copper electrode is consistent with the width of a fan blade of the rotor.

In a specific embodiment, the rotor 1 and the stator 2 are cylindrical, are sleeved with each other, and can be prepared by three-dimensional (3D) printing. The cylindrical stator is prepared by 3D printing, and four grooves evenly distributed are formed on a cylinder wall to fix the plant fiber brush 5. The rotor is also prepared by 3D printing; and the rotor includes 4 or more fan blades, a center of the rotor is a hollow structure, and based on this hollow structure, the rotor can be fixed on a shaft.

A layer of grid-like copper electrodes prepared by an FPCB technology is attached to an inner wall of a shell of the stator 2, and the width of a grid of the copper electrode is consistent with the width of a fan blade of the rotor.

### A) Improvement Implementations and Tests of the Tribo-Electronegative Material 4:

In a specific embodiment, a control group (Control) and 5 experimental groups (ICP-1, ICP-2, ICP-3, ICP-4, and ICP-5) are set.

A treatment process in the experimental groups is as follows:
(1) Cleaning of a PVC film: The PVC film is ultrasonically cleaned in absolute ethanol for 5 min to 10 min and then in deionized water for 5 min to 10 min, and then dried to obtain a clean PVC film.
(2) The clean PVC film is placed in a carrier for plasma etching, and the carrier is delivered to a cavity of a plasma dry etching device.
(3) The plasma dry etching device is vacuumed to maintain a stable pressure, and a process including a first stage and a second stage is conducted.

The etching of the PVC film in the experimental group is divided into stages 1 and 2, and details are shown in Table 1:

TABLE 1

| | Stage 1 (10 min) | | | | | | | |
|---|---|---|---|---|---|---|---|---|
| | | | Radio | Stage 2 (10 s) | | | | |
| | Intro- | | frequency | Intro- | | | | |
| | duction | ICP | (RF) | duction | ICP | RF | | |
| | of a gas | power | power | of a gas | power | power | Ra | T |
| Sample | (sccm) | (W) | (W) | (sccm) | (W) | (W) | (nm) | (μm) |
| Control | | | / | | | | 40.87 | 31.16 |
| ICP-1 | | | 10 | | | 10 | 61.9 | 27.76 |
| ICP-2 | O₂:15 | | 20 | | | 20 | 58.14 | 26.37 |
| ICP-3 | CHF₃:45 | 100 | 25 | C₄F₈:50 | 100 | 25 | 47.91 | 21.39 |
| ICP-4 | | | 30 | | | 30 | 50.27 | 26.41 |
| ICP-5 | | | 40 | | | 40 | 90.48 | 28.13 |

The first stage: 15 sccm O₂ and 45 sccm CHF₃ are introduced; an ICP power is 100 W; RF powers for ICP-1, ICP-2, ICP-3, ICP-4, and ICP-5 are 10 W, 20 W, 25 W, 30 W, and 40 W, respectively; and an etching time is 10 min.

The second stage: 50 sccm C₄F₈ is introduced; an ICP power is 100 W; RF powers for ICP-1, ICP-2, ICP-3, ICP-4, and ICP-5 are 10 W, 20 W, 25 W, 30 W, and 40 W, respectively; and an etching time is 10 s.

In the control group (Control), a gas is introduced at neither of the two stages; and the 5 experimental groups (ICP-1, ICP-2, ICP-3, ICP-4, and ICP-5) each include the two treatment stages (as shown in Table 1), and the 5 experimental groups have different RF treatment powers at the second stage.
(4) After the etching is completed, the device is allowed to reach an ambient pressure state.
(5) A resulting PVC film is taken out.

In the control group, after being cleaned in step (1), the PVC film does not undergo any treatment.

### Example 1

A method for improving the triboelectric output performance of a PVC film based on an ICP dry etching technology was provided, including the following steps:
S1: Cleaning of a PVC film: The PVC film cut to a size of 4 cm*4 cm was ultrasonically cleaned in absolute ethanol for 10 min and then in deionized water for 10 min, and then dried to obtain a clean PVC film.
S2: The clean PVC film was placed in a carrier for plasma etching, and the carrier was delivered to a cavity of a plasma dry etching device.
S3: The plasma dry etching device was vacuumed to maintain a stable pressure, and an etching process including a first stage and a second stage was conducted. The first stage: 15 sccm O₂ and 45 sccm CHF₃ were introduced, an ICP power was 100 W, an RF power was 10 W, and an etching time was 10 min; and the second stage: 50 sccm C₄F₈ was introduced, an ICP power was 100 W, an RF power was 10 W, and an etching time was 10 s.
S4: After the etching was completed, the device was allowed to reach an ambient pressure state.
S5: An etched PVC film ICP-1 was taken out.

### Example 2

The steps in Example 2 were the same as the steps in Example 1, except that:
in S3, an RF power was 20 W; and
in S5, an etched PVC film ICP-2 was taken out.

### Example 3

The steps in Example 2 were the same as the steps in Example 1, except that:
in S3, an RF power was 25 W; and
in S5, an etched PVC film ICP-3 was taken out.

### Example 4

The steps in Example 2 were the same as the steps in Example 1, except that:
in S3, an RF power was 30 W; and
in S5, an etched PVC film ICP-4 was taken out.

### Example 5

The steps in Example 2 were the same as the steps in Example 1, except that:
in S3, an RF power was 40 W; and
in S5, an etched PVC film ICP-5 was taken out.

### Example 6

A PVC film cut to a size of 4 cm*4 cm was ultrasonically cleaned in absolute ethanol for 10 min and then in deionized water for 10 min, and then dried to obtain a clean PVC film as a control group, which was named a control film.

SEM images of 6 PVC films prepared in Examples 1 to 6 are shown in FIG. 18. There are some microcracks randomly distributed on a surface of the untreated control film, and these microcracks are produced during transportation and cleaning. After ICP etching, these microcracks gradually disappear, and nano-bumps are evenly distributed on the film. With the increase of an RF power, an aspect ratio of the nano-bumps gradually increases, and an obvious nano-structure is gradually formed, which is caused by different crystalline regions of the PVC material. PVC includes a crystalline region and a non-crystalline region, and ICP has different etching rates in different regions. The non-crystalline region with a low crystallinity degree is preferentially dissociated at a high etching level, while the crystalline region exhibits a low etching level, resulting in the formation of a nanomaterial on a surface. With the increase of an RF power, both the surface roughness and the etching uniformity increase. When the power exceeds 25 W, an etching power is too high, and nano-bumps are entangled and aggregated, resulting in deteriorated uniformity. Test results show that the morphology of an ICP-etched surface of a PVC film changes, and ICP-3 presents a uniform and dense nano-textured structure.

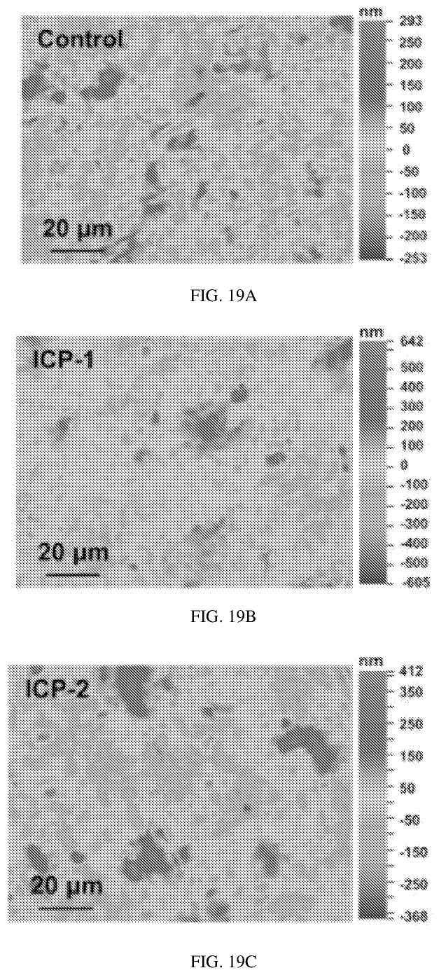

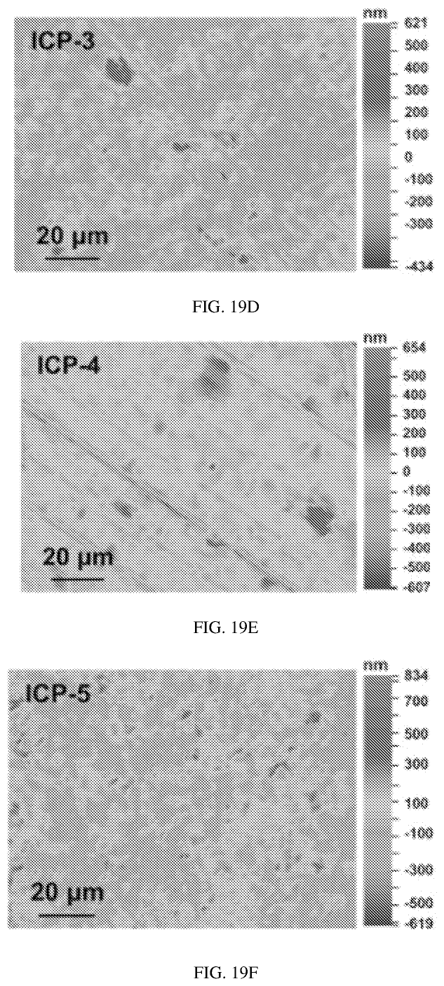

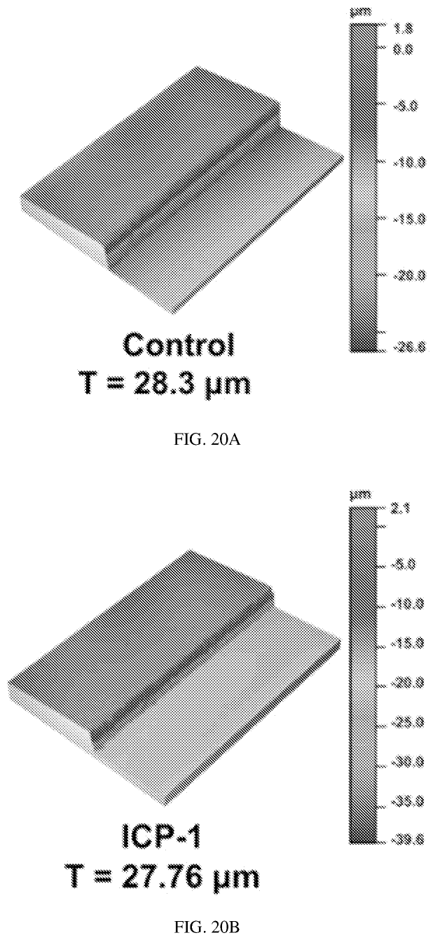

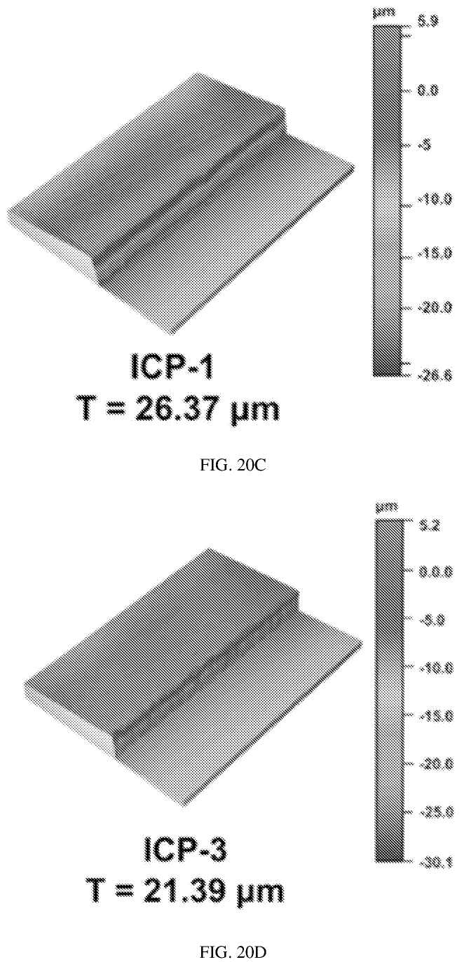

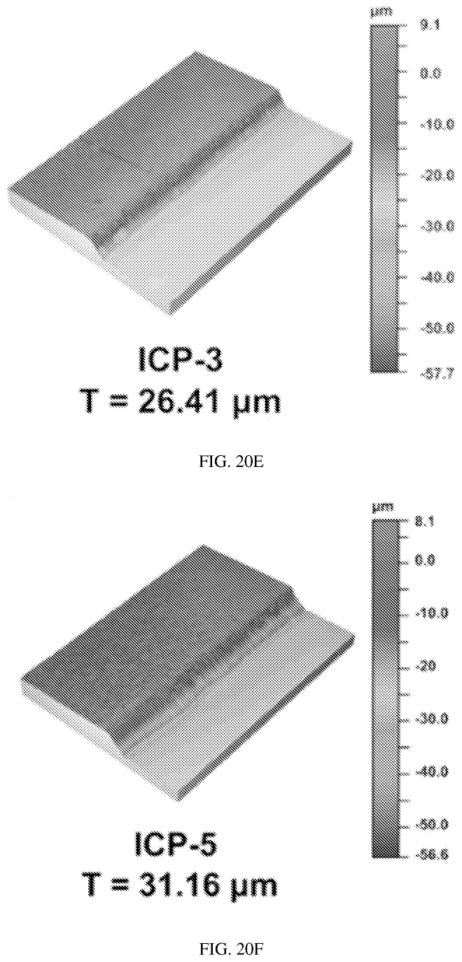

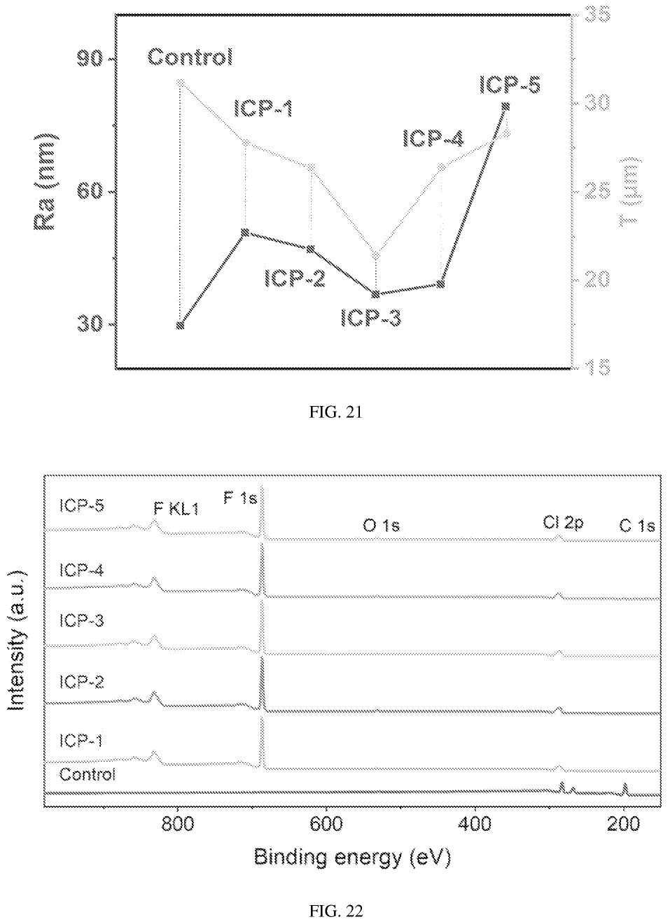

The PVC films of Examples 1 to 6 were subjected to imaging analysis by WLI (FIG. 19A to FIG. 21). Test results show that arithmetic mean roughness values (Ra) and mean thickness values (T) of the plasma-etched films (ICP1-5) decrease first and then increase with the increase of an RF power; and the untreated film (control) has a minimum Ra and a maximum T, indicating that the PVC film is successfully etched by the plasma dry etching method, and compared with the untreated film, the etched film has increased roughness, an increased SSA, and an enhanced surface charge-carrying capacity.

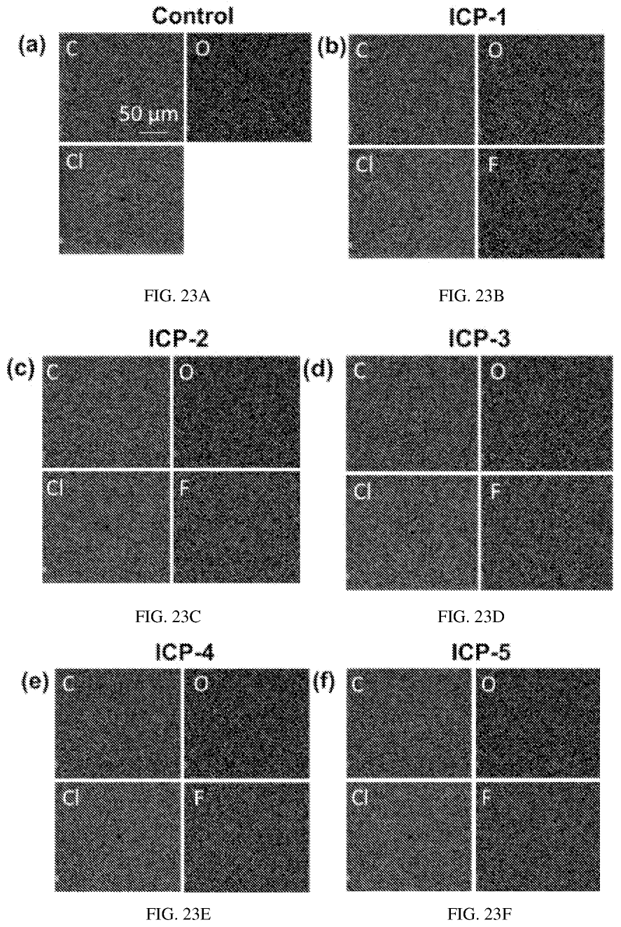

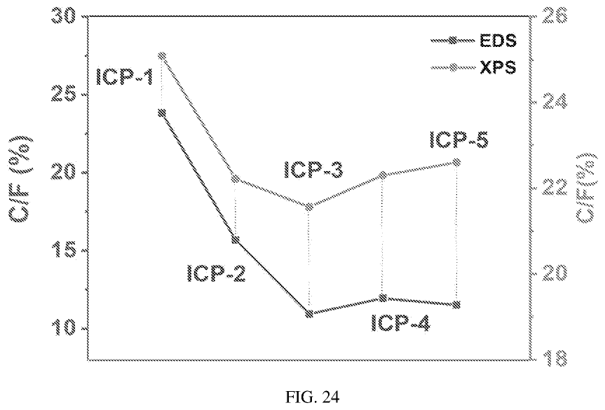

The 6 PVC films of Examples 1 to 6 were characterized by XPS (FIG. 22) and EDS (FIGS. 23A-23F). Characterization results show that, in addition to forming a rough nano-textured structure on a surface of a film, the ICP etching method introduces F and a corresponding functional group. As shown in FIG. 22, the untreated film (control) is composed mainly of C, and a small amount of O in the film may be introduced during resin synthesis or film processing. For the ICP-etched films, with the increase of an RF power, an F content gradually increases, and a C content gradually decreases; and ICP-3 has a minimum C/F ratio (21.56%), indicating that a maximum F content is introduced during this process (FIG. 24). Test results show that the etched PVC film ICP-3 has a maximum F content and optimal triboelectronegativity.

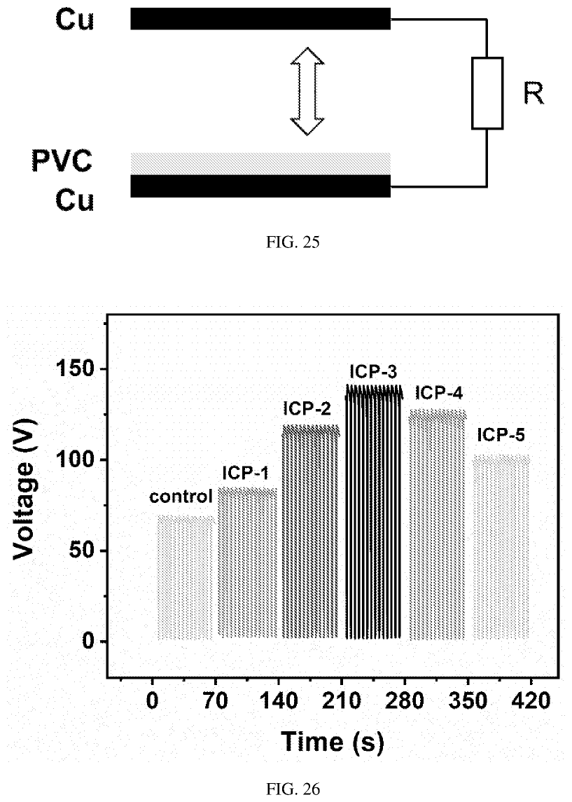

A copper electrode is attached to a back side of each of the 6 PVC films prepared in Examples 1 to 6, and further each PVC film and another copper electrode constitute a vertical contact-separation mode TENG (FIG. 25). Two wires are led out from upper and lower copper electrodes to connect two ends of a multimeter, respectively, a same force is controlled to be applied to the TENG, and an electrical signal output by the TENG is recorded by the multimeter (FIG. 26). Test results show that TENG prepared with the plasma-etched PVC film has a higher output voltage than TENG prepared with the untreated film, indicating that the plasma etching can effectively improve the triboelectric performance of a PVC film. TENG prepared with the film ICP-3 has a maximum output voltage, indicating that an etched PVC film obtained under the etching parameters of ICP-3 exhibits the optimal triboelectric performance.

### B) Specific Implementation of TENG:

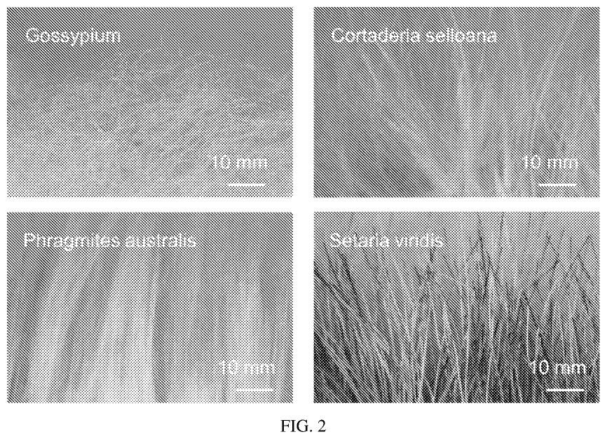

A preparation process of the soft-contact and low-damping TENG (FIG. 1) of the present disclosure is as follows:
1. Preparation of a plant fiber brush: A natural plant fiber is naturally air-dried and then fixed in two acrylic strips by a glue to obtain the plant fiber brush (FIG. 2).
2. Preparation of a tribo-electronegative material: In a specific embodiment, a tribo-electronegative material of the TENG can be selected from PVC, polyethylene (PE), fluorinated ethylene-propylene copolymer (FEP), polytetrafluoroethylene (Teflon), PI, and like.
3. The TENG is prepared through 3D printing, where integrated rotor 1 is fixed by a shaft, tribo-electronegative material layer 4 is attached to an outer side of the rotor 1, and air gap 6 is formed between the tribo-electronegative material 4 and copper electrode 3 on stator 2; four rectangular through holes evenly distributed are formed on a cylinder of the stator 2 to fix the plant fiber brush 5; and the plant fiber brush 5 passes through the rectangular through holes inward in a radial direction and then is fixed in the rectangular through holes, and a length of the plant fiber brush 5 is greater than the air gap 6, such that the plant fiber brush 5 is in contact with the tribo-electronegative material attached to the rotor 1. A grid-like flexible copper electrode is manufactured by an FPCB technology; and the grid-like flexible copper electrode includes two groups of electrodes arranged at an interval, where copper electrodes of a same group are connected to each other, a copper electrode of one group is not connected to a copper electrode of the other group, and two wires are led out from the two groups of copper electrodes, respectively.

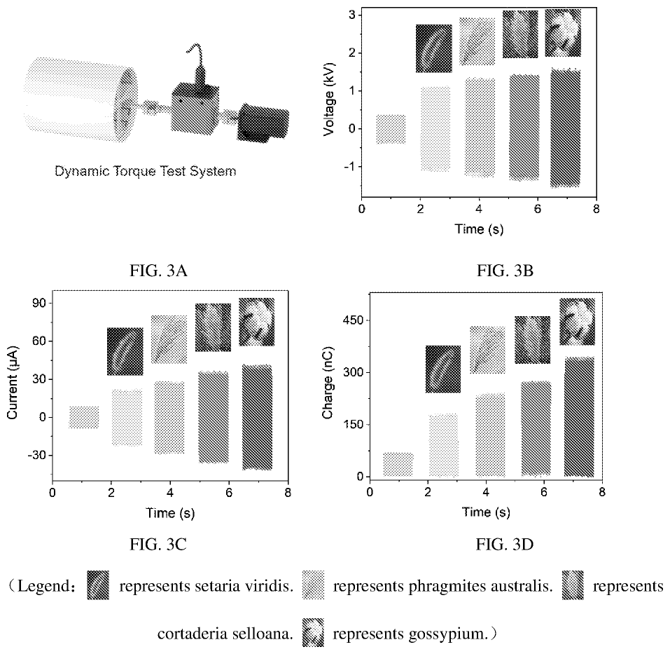

In the present disclosure, a TENG without a plant fiber brush and four independent-layer soft-contact and low-damping TENGs including Gossypium, Cortaderia selloana, Phragmites australis, and Setaria viridis plant fiber brushes respectively are prepared. A dynamic torque system shown in FIG. 3A was used to test output electrical signals of the five TENGs, and abilities of the different plant fiber brushes to supplement charges as soft-contact materials were compared accordingly. A multimeter was used to test output voltages (FIG. 3B), output currents (FIG. 3C), and transferred charge amounts (FIG. 3D) of brush-free PFB-TENG, Setaria viridis brush-based PFB-TENG, Phragmites australis brush-based PFB-TENG, Cortaderia selloana brush-based PFB-TENG, and Gossypium brush-based PFB-TENG. It can be seen from FIGS. 3B-3D that PFB-TENG prepared with the Gossypium brush as a soft-contact material has the optimal output electrical performance. Experimental results show that (1) the use of a plant fiber brush as a soft-contact material can significantly improve an output electrical signal of TENG compared with the case of no brush; and (2) the Gossypium fiber brush has a higher ability to complement charges than the other three plant fiber brushes.

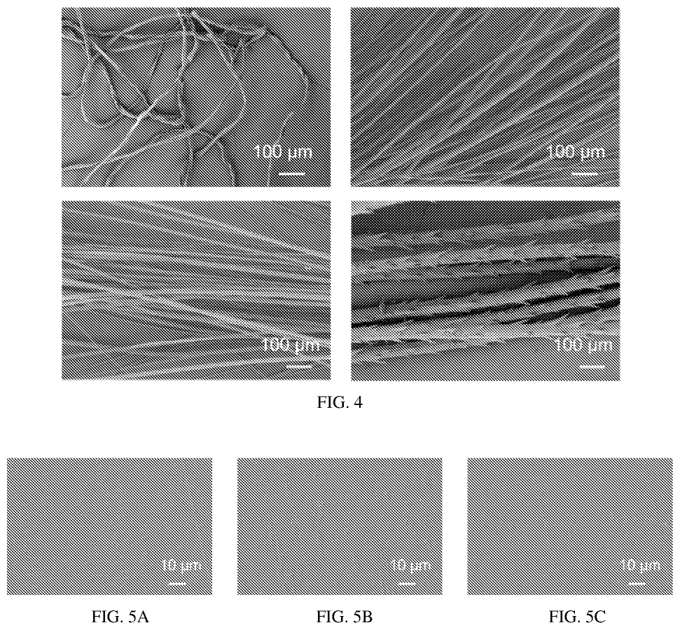

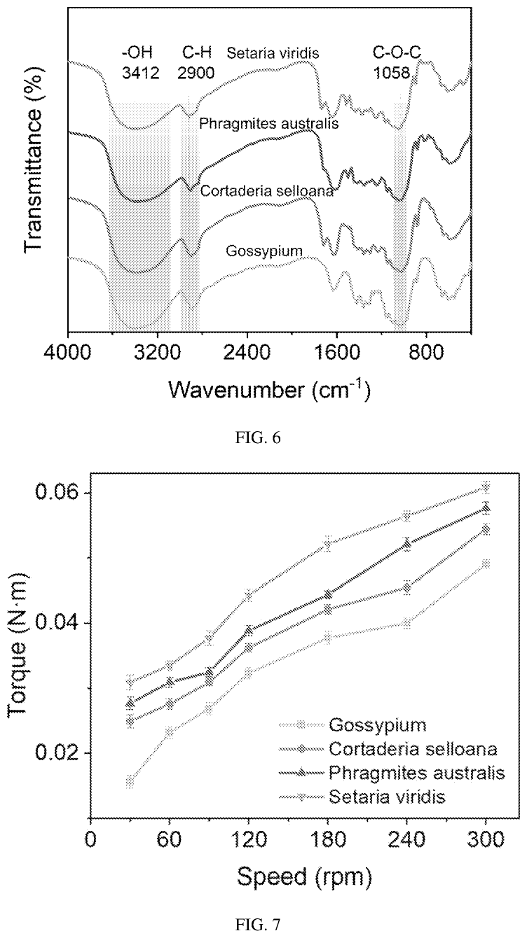

FIG. 4 shows SEM images of four plant fibers of Gossypium, Cortaderia selloana, Phragmites australis, and Setaria viridis. FIG. 6 shows FT-IR characterization results of four plant fibers, where the left panel shows that the four plant fiber brushes include characteristic groups of cellulose, and main components of the four plant fiber brushes all are cellulose; and the right panel shows that groups of Setaria viridis, Phragmites australis, Cortaderia selloana, and Gossypium fibers at 3,412 cm⁻¹ have a redshift. It should be noted that this redshift law also conforms to a ranking order of triboelectropositivity of the five plant fiber brushes.

FIGS. 5A-5C show SEM images of a PVC tribo-electronegative material. The PVC film is cleaned three times with each of ethanol and clean water, and then dried at 40° C. FIG. 5A is an SEM image of a cleaned PVC film, and scratches on the film may be produced during production and transportation of the PVC film. FIG. 5B is an SEM image of the cleaned PVC film rubbed against a copper electrode 30,000 times, and it can be seen that many scratches are produced on the film. FIG. 5C is an SEM image of the PVC film rubbed against a Gossypium fiber brush 30,000 times, and it can be seen that there are almost no scratches on the film, which is similar to a surface condition of the cleaned PVC film. The results show that the use of the Gossypium fiber brush as a soft-contact dielectric material can effectively reduce wear of the PVC tribo-electronegative material, thereby increasing the durability of TENG.

FIG. 6 shows FT-IR characterization results of four plant fibers, and it can be seen from the characterization results that a main component of the four plant fiber brushes is cellulose.

FIG. 7 shows working damping values when four different plant fiber brushes are used as charge-supplement materials, and it can be seen from the figure that damping values produced by the four plant fiber brushes are ranked as follows from largest to smallest: Setaria viridis brush>Phragmites australis brush>Cortaderia selloana brush>Gossypium brush; and the damping values of the four plant fiber brushes all are lower than 0.06 N·m, where the Gossypium brush leads to the smallest damping values at different rotational speeds, which all are lower than 0.05 N·m.

FIG. 8 is a histogram of point integral values of hydroxyl contents in four fiber brushes. Gossypium has a maximum hydroxyl content, and hydroxyl is an electron-donating group. Therefore, Gossypium has the strongest electron-donating ability. The hydroxyl contents in the four fiber brushes are positively correlated with an electron-donating ability of cellulose, that is, the higher the hydroxyl content, the stronger the electron-donating ability.

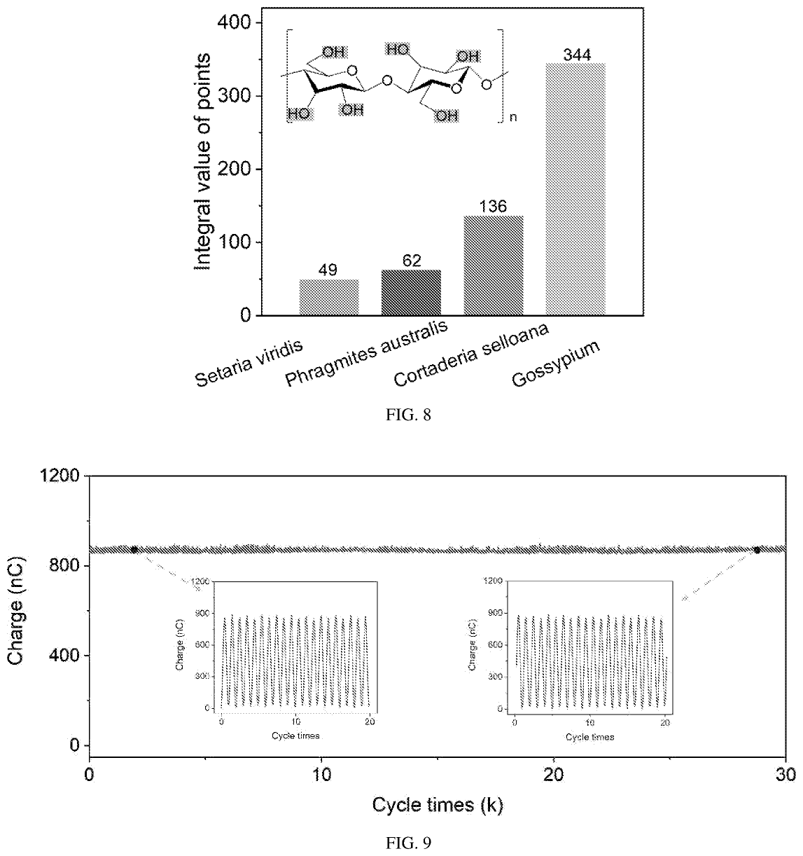

FIG. 9 shows the cycling stability of a soft-contact and low-damping TENG prepared based on a Gossypium fiber. Experimental results show that an output charge amount of the TENG is hardly decreased after 30,000 operation cycles, indicating that the designed plant fiber brush-based (with a Gossypium fiber brush as an example) soft-contact and low-damping TENG has excellent working stability.

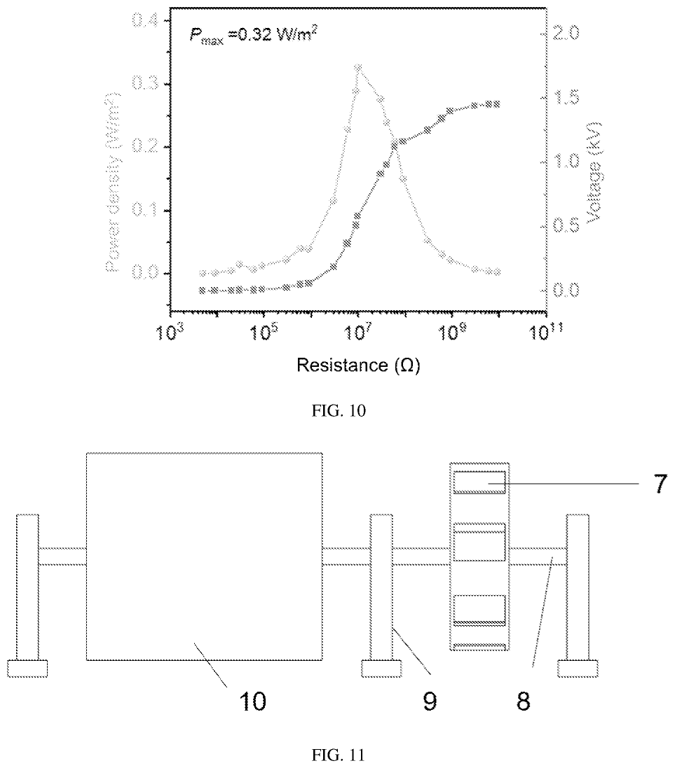

FIG. 10 shows matched voltages and output power densities of a soft-contact and low-damping TENG prepared based on a Gossypium fiber at different external resistances, and it can be seen that a maximum power density can reach 0.32 W/m².

### C) Specific Implementation of a Triboelectric Nano-Power Generation Device:

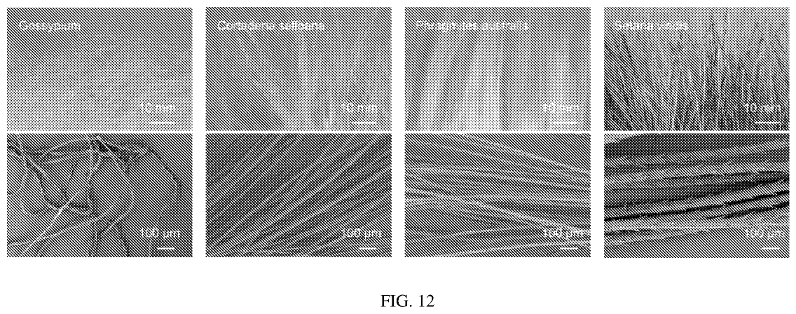

A preparation process of this embodiment is as follows:
S1: Preparation of a plant fiber brush: A natural plant fiber is naturally air-dried and then fixed in two acrylic strips by a glue to obtain the plant fiber brush (FIG. 12).
S2: Preparation of a tribo-electronegative material: In a specific embodiment, a tribo-electronegative material of the TENG can be selected from PVC, PE, FEP, Teflon, PI, and like.
S3: The TENG is prepared through 3D printing, where integrated rotor 1 is fixed by a shaft, tribo-electronegative material layer 4 is attached to an outer side of the rotor 1, and air gap 6 is formed between the tribo-electronegative material 4 and copper electrode 3 on stator 2; four rectangular through holes evenly distributed are formed on a cylinder of the stator 2 to fix the plant fiber brush 5; and the plant fiber brush 5 passes through the rectangular through holes inward in a radial direction and then is fixed in the rectangular through holes, and a length of the plant fiber brush 5 is greater than the air gap 6, such that the plant fiber brush 5 is in contact with the tribo-electronegative material attached to the rotor 1. A grid-like flexible copper electrode is manufactured by an FPCB technology; and the grid-like flexible copper electrode includes two groups of electrodes arranged at an interval, where copper electrodes of a same group are connected to each other, a copper electrode of one group is not connected to a copper electrode of the other group, and two wires are led out from the two groups of copper electrodes, respectively, as shown in FIG. 11.
S4: The two wires led out are connected to two pins at an alternating current (AC) end of a bridge rectifier, and the other two pins of the bridge rectifier are connected to an external electrical energy-receiving device, such that a complete PFB-TENG is obtained.
S5: The PFB-TENG and a waterwheel are fixed on a same shaft, and the waterwheel drives, through the shaft under an action of a water flow, the PFB-TENG to operate to allow the harvest of low-flow-rate water energy.

### Specific Implementation Tests

Damping values of independent-layer soft-contact triboelectric nano-power generation devices prepared with four different plant fiber brushes of Gossypium, Cortaderia selloana, Phragmites australis, and Setaria viridis plant fiber brushes (FIG. 12) respectively at different rotational speeds are compared. A torque test system was used to compare damping values of triboelectric nano-power generation devices prepared with different plant fiber brushes at different rotational speeds, and PFB-TENG with a small damping value was screened out to harvest low-flow-rate water energy. Experimental results (FIG. 7) show that, when a Setaria viridis brush, a Phragmites australis brush, a Cortaderia selloana brush, and a Gossypium brush are adopted as charge-supplement materials, a working damping of the device is lower than 0.06 N·m, where the Gossypium brush leads to the smallest damping values at different rotational speeds, which all are lower than 0.05 N·m and can be as low as 0.015 N·m. At a same rotational speed, the PFB-TENG prepared with the Gossypium fiber brush produces a minimum damping value when operating. Therefore, the Gossypium fiber is preferred as a soft-contact material for preparation of a low-damping triboelectric nano-power generation device.

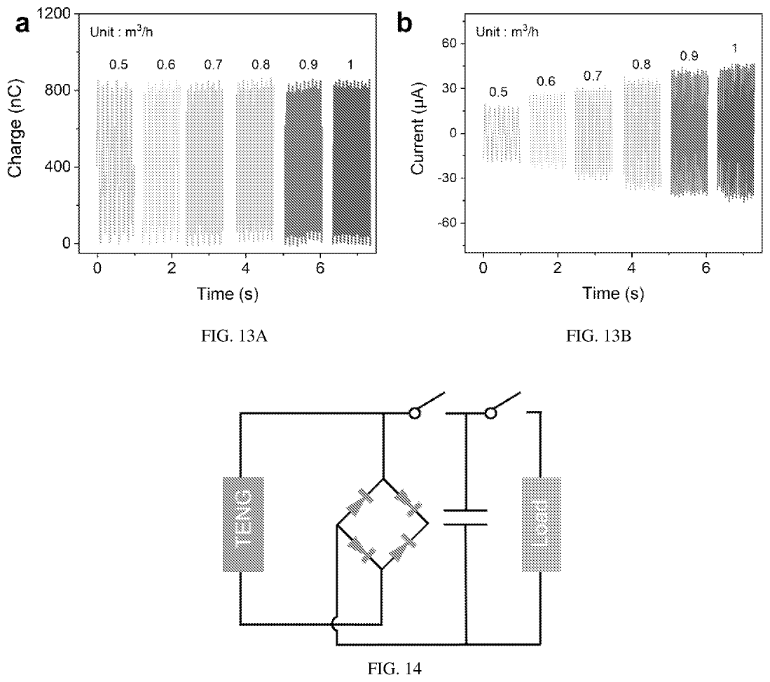

With reference to Example 1, a plant fiber-based soft-contact and low-damping triboelectric nano-power generation device was prepared with a Gossypium fiber brush, and two wires were led out from the copper electrode of the triboelectric nano-power generation device and connected to two electrodes of a multimeter, respectively. The triboelectric nano-power generation device was driven to operate under actions of water flows at different flow rates (0.5 m³/h, 0.6 m³/h, 0.7 m³/h, 0.8 m³/h, 0.9 m³/h, and 1 m³/h), and a charge amount and current output on the electrode of the TENG were measured by a multimeter. FIGS. 13A-13B show transferred charge amounts (FIG. 13A) and short-circuit currents (FIG. 13B) of PFB-TENG under actions of water flows at different flow rates. The experimental results show that the PFB-TENG prepared with the Gossypium fiber brush can allow the harvest of water energy at different flow rates of 0.5 m³/h, 0.6 m³/h, 0.7 m³/h, 0.8 m³/h, 0.9 m³/h, and 1 m³/h, and can allow the harvest of water energy at a minimum flow rate of 0.5 m³/h. The experimental results show that the plant fiber-based soft-contact and low-damping triboelectric nano-power generation device can allow the harvest of low-damping water energy.

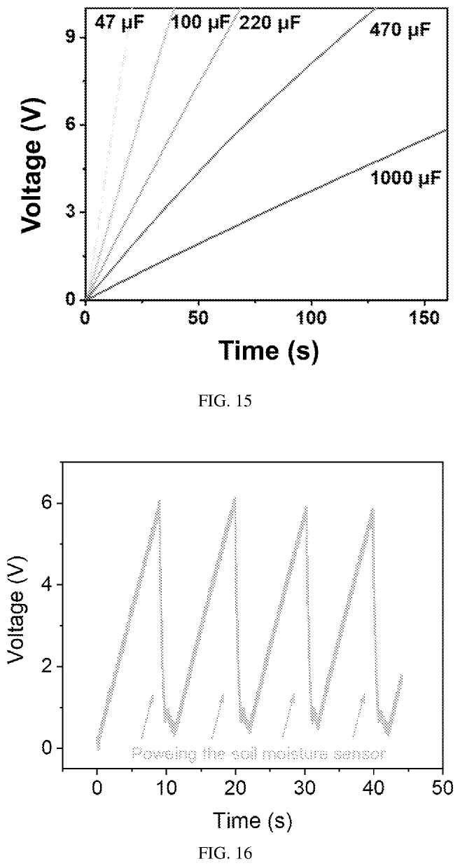

With reference to Example 1, a plant fiber-based soft-contact and low-damping triboelectric nano-power generation device was prepared with a Gossypium fiber brush, and two wires were led out from the copper electrode of the triboelectric nano-power generation device and connected to two sides of a bridge rectifier; and rectification was conducted, and then a capacitor was charged by the device. FIG. 14 is an equivalent circuit diagram in which the plant fiber-based soft-contact and low-damping triboelectric nano-power generation device configured to harvest irrigation energy in the present disclosure serves as a power supply for a load resistor or capacitor. FIG. 15 shows voltage changes of different capacitors charged by PFB-TENG driven by a water flow over time.

With reference to Example 1, a plant fiber-based soft-contact and low-damping triboelectric nano-power generation device was prepared with a Gossypium fiber brush, and two wires were led out from the copper electrode of the triboelectric nano-power generation device and connected to two sides of a bridge rectifier; and rectification was conducted, then a capacitor was charged by the device, and the capacitor stored energy for powering a soil sensor. FIG. 16 shows some work cycles on a voltage curve of the soil sensor powered by PFB-TENG driven by a water flow. The experimental results show that PFB-TENG can allow the harvest of water energy and power an agricultural sensor, and can serve as a power supply for a sensor in smart agriculture.

### Example 1

A Gossypium fiber brush-based TENG is provided, including: rotor 1, stator 2, copper electrode 3, tribo-electronegative material 4, and Gossypium fiber brush 5, where the rotor 1 is located inside the stator 2; an inner circumferential surface of the stator 2 is covered with the copper electrode 3, and at least one position on an outer circumferential surface of the rotor 1 is provided with the tribo-electronegative material 4; the tribo-electronegative material 4 is not in contact with the copper electrode 3, and air gap 6 is formed between the tribo-electronegative material 4 and the copper electrode 3; and at least one position on the inner circumferential surface of the stator 2 is provided with the plant fiber brush 5. The tribo-electronegative material is an untreated PVC film control.

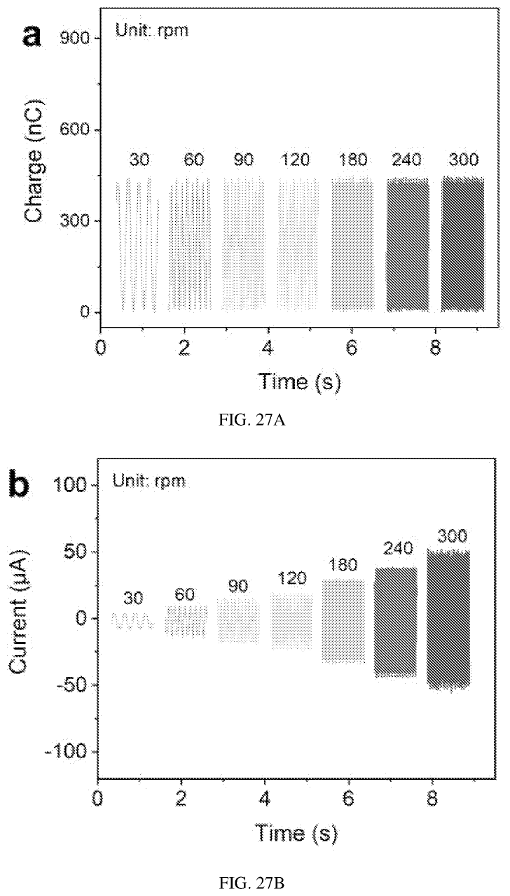

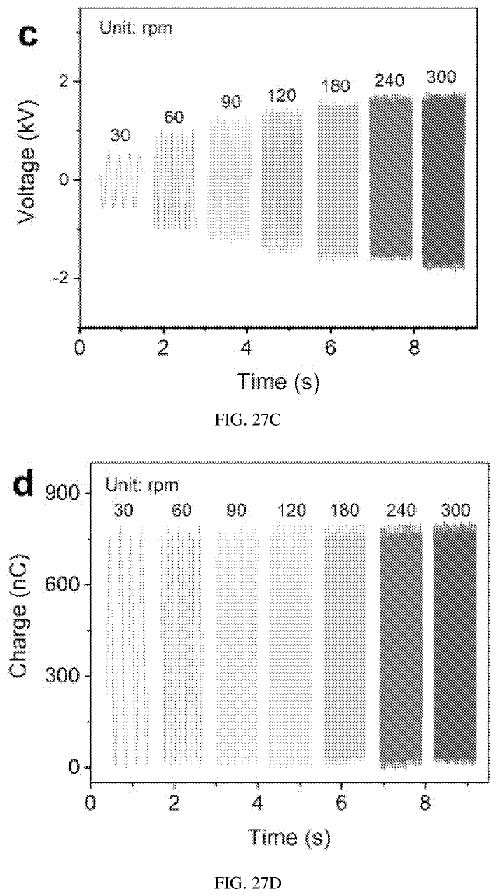

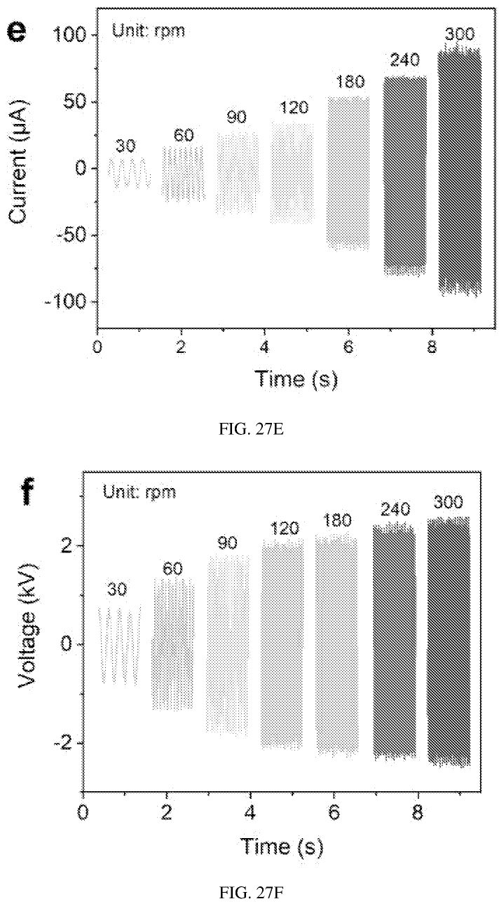

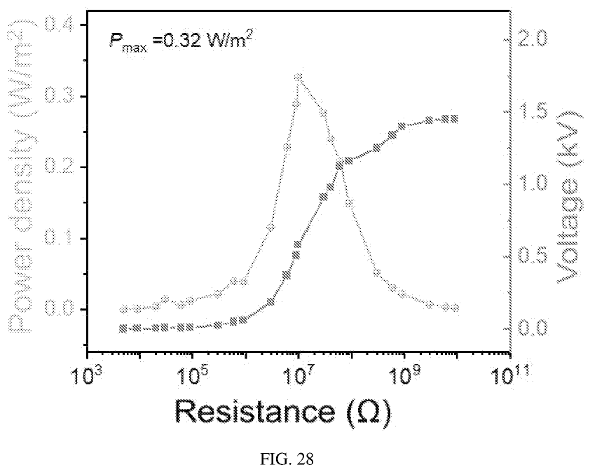

An electrometer was used to test transferred charge amounts and output currents and voltages of the TENG prepared with the untreated PVC film at different rotational speeds, and test results were shown in FIGS. 27A-27C. Output power densities of the TENG at different matched resistances were shown in FIG. 28, where the etched PVC film ICP-3 had a maximum power density of 0.33 W/m².

### Example 2

A Gossypium fiber brush-based TENG is provided, including: rotor 1, stator 2, copper electrode 3, tribo-electronegative material 4, and plant fiber brush 5, where the rotor 1 is located inside the stator 2; an inner circumferential surface of the stator 2 is covered with the copper electrode 3, and at least one position on an outer circumferential surface of the rotor 1 is provided with the tribo-electronegative material 4; the tribo-electronegative material 4 is not in contact with the copper electrode 3, and air gap 6 is formed between the tribo-electronegative material 4 and the copper electrode 3; and at least one position on the inner circumferential surface of the stator 2 is provided with the plant fiber brush 5. The tribo-electronegative material is an ICP-etched PVC film.

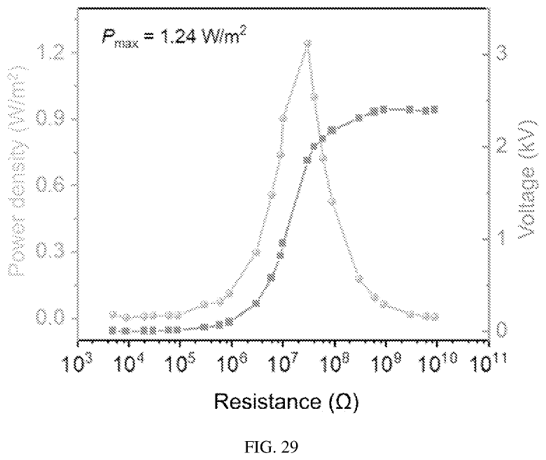

An electrometer was used to test transferred charge amounts and output currents and voltages of the TENG prepared with the control film at different rotational speeds, and test results were shown in FIGS. 27D-27F. Output power densities of the TENG at different matched resistances were shown in FIG. 29, where the etched PVC film ICP-3 had a maximum power density of 1.14 W/m², and compared with the untreated PVC film, the output power density of TENG is increased by about 4 times. Therefore, the etched PVC film can effectively improve the triboelectronegativity of the film, thereby improving an output power density of TENG.

What is claimed is:

1. A plant fiber brush-based soft-contact and low-damping triboelectric nanogenerator (TENG), comprising:
a rotor, a stator, a copper electrode, a tribo-electronegative material, and a plant fiber brush, wherein the rotor is located inside the stator; an inner circumferential surface of the stator is covered with the copper electrode, and at least one position on an outer circumferential surface of the rotor is provided with the tribo-electronegative material; the tribo-electronegative material is not in contact with the copper electrode, and an air gap is formed between the tribo-electronegative material and the copper electrode; and at least one position on the inner circumferential surface of the stator is provided with the plant fiber brush.

2. The plant fiber brush-based soft-contact and low-damping TENG according to claim 1, wherein the plant fiber brush is prepared from a natural plant fiber, comprising soft fiber material-containing plants such as Gossypium, Phragmites australis, Cortaderia selloana, and Setaria viridis.

3. The plant fiber brush-based soft-contact and low-damping TENG according to claim 1, wherein the outer circumferential surface of the rotor is provided with a plurality of tribo-electronegative materials in a circumferential direction.

4. The plant fiber brush-based soft-contact and low-damping TENG according to claim 1, wherein the copper electrode comprises interdigital electrodes arranged at an interval in an axial direction; and the interdigital electrodes are arranged on a substrate, and the substrate is fixed on and covers the inner circumferential surface of the stator.

5. The plant fiber brush-based soft-contact and low-damping TENG according to claim 1, wherein the tribo-electronegative material is fixedly attached to a substrate, and is not in contact with the copper electrode.

6. A use of the plant fiber brush-based soft-contact and low-damping TENG according to claim 1 in harvest of irrigation energy.

7. A plant fiber-based triboelectric nano-power generation device configured to harvest low-flow-rate water energy, comprising the TENG according to claim 1 and a waterwheel driving mechanism, wherein the rotor of the TENG is coaxially connected to a driving shaft of the waterwheel driving mechanism, and the waterwheel driving mechanism is driven under an action of a water flow to operate so as to drive the TENG to operate.

8. The plant fiber-based triboelectric nano-power generation device configured to harvest low-flow-rate water energy according to claim 7, wherein the waterwheel driving mechanism comprises a waterwheel, the driving shaft, and a bearing seat; and the waterwheel is sleeved on the driving shaft, the driving shaft is supported on the bearing seat, and the driving shaft is coaxially connected to the rotor.

9. A use of the plant fiber-based triboelectric nano-power generation device according to claim 7 in harvest of irrigation energy or water energy.

10. The TENG according to claim 1, wherein a preparation method of the tribo-electronegative material is as follows: etching an upper surface of a film by an inductively coupled plasma (ICP) dry etching instrument to form a nano-textured structure on the upper surface of the film; and subjecting the upper surface of the film to a deposition treatment by an ICP etching instrument to deposit a fluorocarbon layer on an upper surface of the nano-textured structure.

11. The TENG according to claim 10, wherein the preparation method specifically comprises the following steps:
(1) cleaning of a polyvinyl chloride (PVC) film: ultrasonically cleaning the PVC film in absolute ethanol for 5 min to 10 min and then in deionized water for 5 min to 10 min, and drying a cleaned PVC film to obtain a clean PVC film;
(2) placing the clean PVC film in a carrier for plasma etching, and delivering the carrier to a cavity of a plasma dry etching device;
(3) vacuuming the plasma dry etching device to maintain a stable pressure, and allowing a process comprising two stages of etching and deposition; and
(4) after the process is completed, controlling the plasma dry etching device to reach an ambient pressure state, and taking a resulting PVC film out.

12. The TENG according to claim 11, wherein the two stages in step (3) are as follows:
a first stage: introducing 15 sccm O₂ and 45 sccm CHF₃, controlling an ICP power at 100 W, and conducting etching for 10 min; and
a second stage: introducing 50 sccm C₄F₈, controlling an ICP power at 100 W, and conducting deposition for 10 s.

13. The use of the plant fiber brush-based soft-contact and low-damping TENG according to claim 6, wherein in the plant fiber brush-based soft-contact and low-damping TENG, the plant fiber brush is prepared from a natural plant fiber, comprising soft fiber material-containing plants such as Gossypium, Phragmites australis, Cortaderia selloana, and Setaria viridis.

14. The use of the plant fiber brush-based soft-contact and low-damping TENG according to claim 6, wherein in the plant fiber brush-based soft-contact and low-damping TENG, the outer circumferential surface of the rotor is provided with a plurality of tribo-electronegative materials in a circumferential direction.

15. The use of the plant fiber brush-based soft-contact and low-damping TENG according to claim 6, wherein in the plant fiber brush-based soft-contact and low-damping TENG, the copper electrode comprises interdigital electrodes arranged at an interval in an axial direction; and the interdigital electrodes are arranged on a substrate, and the substrate is fixed on and covers the inner circumferential surface of the stator.

16. The use of the plant fiber brush-based soft-contact and low-damping TENG according to claim 6, wherein in the plant fiber brush-based soft-contact and low-damping TENG, the tribo-electronegative material is fixedly attached to a substrate, and is not in contact with the copper electrode.

17. The plant fiber-based triboelectric nano-power generation device configured to harvest low-flow-rate water energy according to claim 7, wherein in the plant fiber brush-based soft-contact and low-damping TENG, the plant fiber brush is prepared from a natural plant fiber, comprising soft fiber material-containing plants such as Gossypium, Phragmites australis, Cortaderia selloana, and Setaria viridis.

18. The plant fiber-based triboelectric nano-power generation device configured to harvest low-flow-rate water energy according to claim 7, wherein in the plant fiber brush-based soft-contact and low-damping TENG, the outer circumferential surface of the rotor is provided with a plurality of tribo-electronegative materials in a circumferential direction.

19. The plant fiber-based triboelectric nano-power generation device configured to harvest low-flow-rate water energy according to claim 7, wherein in the plant fiber brush-based soft-contact and low-damping TENG, the copper electrode comprises interdigital electrodes arranged at an interval in an axial direction; and the interdigital electrodes are arranged on a substrate, and the substrate is fixed on and covers the inner circumferential surface of the stator.

20. The plant fiber-based triboelectric nano-power generation device configured to harvest low-flow-rate water energy according to claim 7, wherein in the plant fiber brush-based soft-contact and low-damping TENG, the tribo-electronegative material is fixedly attached to a substrate, and is not in contact with the copper electrode.
